(19) United States
(12) Patent Application Publication
(10) Pub. No.: US 2016/0315263 A1
(43) Pub. Date: Oct. 27, 2016

(54) Deposition Of Organic Photoactive Layers By Means Of Sinter-ing

(71) Applicants: COMPAGNIE GENERALE DES ETABLISSMENTS MICHELIN, Clermont-Ferrand (FR); MICHELIN RECHERCHE ET TECHNIQUE S.A., Granges-Paccot (CH)

(72) Inventors: David Hartmann, Erlangen (DE); Judith Elisabeth Huerdler, Nuernberg (DE); Andreas Kanitz, Hoechstadt (DE); Oliver Schmidt, Erlangen (DE)

(73) Assignee: Siemens Aktiengesellschaft, Muenchen (DE)

(21) Appl. No.: 15/104,639

(22) PCT Filed: Dec. 11, 2014
(86) PCT No.: PCT/EP2014/077331

§ 371 Date: Jun. 15, 2016

(30) Foreign Application Priority Data
Dec. 17, 2013 (DE) 1362812

(51) Int. Cl. H01L 51/00; H01L 51/42; H01L 51/44; C23C 16/455

(52) U.S. Cl. CPC H01L 51/0013; C23C 16/455; H01L 51/4253; H01L 51/441

(57) ABSTRACT

A method is disclosed for producing an organic component including a substrate and at least one layer produced by a sintering process. An organic component produced by such method is also disclosed.

### CROSS-REFERENCE TO RELATED APPLICATIONS

This application is a U.S. National Stage application of International Application No. PCT/EP2014/077311 filed Dec. 11, 2014, which designates the United States of America, and claims priority to DE Application No. 10 2013 226 339.2 filed Dec. 18, 2013, the contents of which are hereby incorporated by reference in their entirety.

### TECHNICAL FIELD

The present invention relates to a method for producing an organic component, comprising a substrate and at least one layer, wherein the at least one layer is produced by means of a sinter process, and also relates to an organic component which is produced by means of the method according to the invention.

### BACKGROUND

Many applications of organic electronics (e.g. organic light-emitting diodes, organic light-emitting electro-chemical cells, organic photovoltaics, organic field effect transistors or organic photodetectors) are currently realized in process technology either via physical gas phase or wet chemical coating or printing methods, wherein these methods can be used for example to construct the respective component architectures. Gas phase deposition is primarily employed here for organically small molecules, wet chemical processing for both small organic molecules and also for polymers.

With (physical) gas phase deposition a vacuum-based coating method is involved. By contrast with chemical gas phase deposition, the initial material is transferred into the gas phase with the aid of physical methods. the gaseous material is subsequently conveyed to the substrate to be coated, where it condenses and forms the target layer. In order that the vapor particles also reach the substrate and are not lost by scattering on the gas particles, the method must be operated in a vacuum. Typical operating pressures lie in the range of around 10⁻⁴ Pa to around 10 Pa. This method thus generally requires a complex process technology.

With wet-chemical deposition small molecules or polymers are put into a solution or a dispersion by means of solvents, additives and/or dispersants and are deposited on a substrate by means of various coating methods. For this process both various coating (e.g. spin, slot dye, spray coating etc.) and also printing technologies (e.g. screen, flexo, gravure printing) are available in order to produce homogeneous wet films. In the case of solutions various individual solvents or solvent mixtures are used for the purposes of producing a more homogeneous layer. Some coating methods need additional additives, in order for example to adapt the viscosity of the solution/dispersion to the coating technology involved. The use of additives can however have an adverse influence on the properties of the component. Furthermore a plurality of small molecules and polymers is not soluble in harmless solvents (e.g. in water or organic solvents such as anisole/phenotol) but only in dangerous, in some cases carcinogenic, solvents such as chlorobenzene, dichlorobenzene, chloroform etc. Any production of components when using such solvents is only possible with increased and costly safety measures, protective housings and personnel training.

For some applications layers with homogeneous layer thicknesses of multiples of 10 to multiples of 100 μm are also needed. Such an application for example would be an organic photo detector sensitive to x-rays, characterized by an x-ray-absorbing layer.

Were a layer of this type to be deposited from the gas phase, the material losses (>90%) and the too low throughput (i.e. layer thickness per unit of time) would make it uneconomic to produce such a component.

If such a layer were to be deposited from the solution, e.g. via slot dye coating, then for stable, typically organic solutions/dispersions, of which the maximum concentration of solids does not generally exceed a threshold of 3% (solid in relation to solvent), a wet film of around 17 mm would have to be layered/coated in order subsequently to obtain a detector layer thickness of 500 μm. Although the coating for such low-viscosity solutions would be conceivable via a type of solvent inclusion, the homogeneous vaporization of the solvent without drying effects in the remaining film, e.g. coffee stain effects or circular or linear breaking-up of the film, is seen as a major challenge. If solvents such as chlorobenzene or dichlorobenzene were also to be used, then the drying problems would also be accompanied by danger to the health of the production personnel. Even the organic materials P3HT and PCBM, which are often used in the literature in organic photovoltaics and photodiode components as hole or electron transporters, are only able to be dissolved in these types of (halogenated) solvents in sufficient solids concentrations.

With many previous wet film, but also gas phase depositions, large volumes of material are likewise lost as a result of the technology used. In such cases the coating is often outwards over the active surface (e.g. with spin coating or spray coating). In most cases the proportion of lost material is not recoverable and amounts to more than 90%.

The problem of “material deposition with high throughput on homogeneous layers of high layer thickness, with low use of materials without complex process technology and above all layer structures without health implications” has thus not been resolved satisfactorily to date.

A demand therefore exists for a layering method for organic materials that makes possible high throughput during the production of homogeneous layers of high layer thickness, with low use of materials without complex process technology and above all layer structures without health implications for the personnel.

### SUMMARY

One embodiment provides a method for producing an organic component, comprising a substrate and at least one layer, wherein the at least one layer is produced by means of a sinter process, comprising (a) Provision of a powder comprising at least one organic semiconductor component; (b) Application of the powder to a substrate; and (c) Exertion of pressure for compressing the powder.

In one embodiment, in step (c) the substrate is heated up before pressure is exerted for compressing the powder.

In one embodiment, the organic semiconductor component consists of at least two compounds.

In one embodiment, the at least two compounds are put into a solution by means of a first solvent, are subsequently precipitated by addition of a further substance and finally the first solvent and the further substance are removed.

In one embodiment, the powder consists of powder grains with a diameter of 0.01 to 200 μm, preferably of 0.5 to 100 μm and especially preferably of 1 to 10 μm.

In one embodiment, the substrate has a first electrical contact and optionally a first intermediate layer.

In one embodiment, after the production of the layer, optionally a second intermediate layer and then a second electrical contact are applied and these are preferably sintered along with the layer.

In one embodiment, the second electrical contact is realized by applying a metallic foil.

In one embodiment, electrical contacts are applied on the part of the powder in step (b) or the compressed powder in step (c).

In one embodiment, the application of the powder is delimited locally, preferably by using a frame, further preferably by using a frame that is coated, at least on its inner side, with an anti-adhesion coating, for example Teflon®.

In one embodiment, the layer, after its production, has a thickness of at least 1 μm, preferably of at least 10 μm, and further preferably of at least 100 μm.

In one embodiment, pressure is exerted by using a stamp or a roll, which are preferably coated with an anti-adhesion coating, for example Teflon®.

Another embodiment provides an organic component, produced in accordance with a method as disclosed above. The organic component may be an electro-optical component, e.g., a photodetector.

### BRIEF DESCRIPTION OF THE DRAWINGS

Aspects and embodiments of the invention are described in detail below with reference to the drawings, in which:

FIG. 1 shows a schematic of the principle functions of a photodiode;

FIG. 2 shows a schematic of a photodiode;

FIG. 3 shows a schematic of a structure of a sinter apparatus for organic layers;

FIG. 4 shows a schematic of a further structure of a sinter apparatus for organic layers;

FIG. 5 shows powder before its compression in the sinter apparatus;

FIG. 6 shows the compressed powder;

FIG. 7 shows the introduction of an aluminum foil as a contact layer before the compression;

FIG. 8 shows the layering of a number of powders before the compression; and

FIG. 9 shows the current-voltage characteristics of a typical inventive photodiode.

### DETAILED DESCRIPTION

According to the present disclosure, particulate, organic semiconductor materials can be deposited from the dry phase using a sinter process.

Some embodiments provide a method for producing an organic component, comprising a substrate and at least one layer, wherein the at least one layer is produced by means of a sinter process, comprising
a) Provision of a powder comprising at least one organic semiconductor component;
b) Application of the powder to a substrate;
c) Exertion of pressure to compress the powder.

Other embodiments provide an organic component produced by the inventive method.

Presented below in detail is a new layering method for organic, electro-optically active materials, namely the sintering of electro-optically active organic powders comprising at least one organic semiconductor component, for example the sintering of single-phase or multi-phase small molecules, polymers and also mixtures of the two. The said layering method could be successfully demonstrated for organic photodiodes and is thus also applicable to other existing classes of components such as e.g. photovoltaic cells, light-emitting diodes or electrochemical cells.

As mentioned above, some embodiments provide a method for producing an organic component, comprising a substrate and at least one layer, wherein the at least one layer is produced by means of a sinter process, comprising
a) Provision of a powder comprising an organic semiconductor component or provision of a powder including at least one organic semiconductor component;
b) Application of the powder to a substrate;
c) Exertion of pressure to compress the powder.

In accordance with specific forms of implementation the organic semiconductor component is semiconducting. Furthermore, in accordance with specific forms of implementation, the layer is an electro-optically active layer.

The substance to be processed may be applied as a powder, including at least one organic semiconductor component or comprising at least one organic semiconductor component, for example comprising electro-optically active organic single-phase or multi-phase small molecules or polymers or mixtures of the two, preferably as a dry powder, to the respective base/substrate of the corresponding component architecture to be layered and is subsequently compressed, while pressure is being exerted, for example with a stamp, a roll etc. at a specific sinter temperature, for example also room temperature of 20-25° C., and sinter time. In this process the particles of the initial material are compressed and the pore spaces are filled. Both solid-phase internal, i.e. material compression without melting of the organic material, and also fluid-phase-internal, i.e. material compression via melting of the organic material (e.g. directly at the contact surface between sinter stamp and organic surface), are conceivable. Through the compression of the molecules using pressure and possibly temperature, the spaces are minimized and compressed such that, when an electrical voltage is applied, electrical charge transport, e.g. via hopping or redox processes, is possible between the individual molecules or polymer strands. In this way homogeneous organic material layers of large (and also small) layer thickness are able to be realized without complex vacuum processes with high throughput and without health risks from possible solvents.

The exertion of pressure is not especially restricted in accordance with the invention and can be achieved by suitable facilities. In accordance with preferred forms of implementation the pressure is exerted by using a stamp or a roll, which is preferably coated with an anti-adhesion coating, for example Teflon®. Coating it with an anti-adhesion coating, for example Teflon®, especially allows very homogeneous surfaces of the layer to be obtained. The use of stamps and/or rolls is also able to be implemented easily in process technology terms. The material of the stamp or the roll is not especially restricted and can comprise aluminum, steel, PVC or Teflon® for example.

The pressure that is exerted is not especially restricted, provided sintering is brought about thereby. In accordance with specific forms of implementation a pressure of 0.1 to 10.00 MPa, further preferably of 0.5 to 200 MPa and especially preferably of 1 to 50 MPa is exerted. The sinter time is also not especially restricted and amounts, in accordance with specific forms of implementation, to 0.1 sec to 60 min, preferably 1 sec to 30 min and especially preferably 5 to 10 min. With a sinter time that is too long no better results are achieved and a deterioration of the layer can result, while sinter times that are too short cannot achieve a sufficient baking of the layer.

In accordance with specific forms of implementation the substrate can be heated up in step c), for example to a temperature of 30 to 300° C., preferably 50 to 200° C., before pressure is exerted to compress the powder. This enables the sinter process to be improved.

The inventively produced layers can be verified and characterized on the basis of the morphology and also the surface properties of the sintered layer (possibly separated or whole-surface melted areas). Possibly indirect conclusions can also be drawn about a sinter process, e.g. through the absence of traces of solvent, additives or dispersants. Examination methods to be considered are as follows: Optical microscopy, raster scan electron microscopy, atomic force microscopy, secondary ion mass microscopy, gas chromatograph microscopy, cyclovoltametry etc.

In some embodiments the substrate is not especially restricted and can comprise all substrates that are normally used in organic components. Thus it can comprise glass, indium tin oxide (ITO), aluminum zinc oxide, doped tin oxide, silicon etc. In accordance with specific forms of implementation the substrate can have a first electrical contact such as a metal, for example Cu or Al, ITO, aluminum zinc oxide, doped tin oxide etc. and optionally a first intermediate layer, such as are present in electro-organic components for example.

Also the organic semiconductor component in the inventive method is not especially restricted. In accordance with specific forms of implementation, the organic semiconductor component includes at least two compounds, which form a bulk hetero junction (BHJ) layer, for example an acceptor material and a donor material. Also a third component, such as a secondary donor polymer of the p type can be contained in specific forms of implementation for example.

A typical representative of a strong electron donator (low electron affinity) is e.g. the conjugated polymer poly-(3-hexylthiophene) (P3HT). Typical materials for electron acceptors (high electron affinity) are fullerene and its derivatives such as e.g. [6,6]-phenyl-C₆₁-butyric acid methyl ester. In addition materials such as polyphenyl vinyls and their derivatives such as cyano derivates CN-PPV, MEH-PPV (poly(2-(2-eythlhexyloxy)-5-methoxy-p-phenylvinylene)), CN-MEH-PPV or phthalocyanine etc. can also be used.

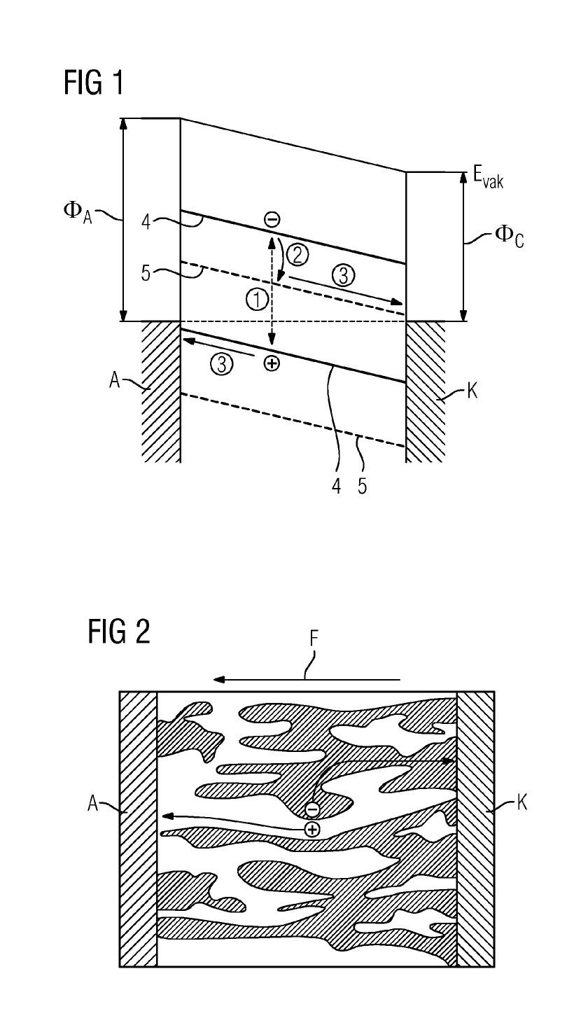

For suitable mixing conditions of acceptor and donator materials the BHJ layer forms a bicontinuous network of electron donators and electron acceptor domains, as is shown in FIG. 2 for an example of a photodiode. The functioning of the organic semiconductor components is demonstrated on the basis of the example of the organic photodiode shown in FIG. 1.

First of all the principle structure and the functioning of the diode will be explained in brief. An organic photodiode may comprise a bulk hetero junction (BHJ) layer that is disposed between two electrodes. Typical electrode materials are e.g. ITO, as transparent anode A and aluminum as (non-) transparent cathode K. For suitable mixing conditions of acceptor and donor materials the BHJ layer forms a bicontinuous network of electron donator and electron acceptor domains (FIGS. 1 and 2).

The principle way in which the organic photodiode functions will be explained with the aid of FIG. 1. If a photon of sufficient energy (hν>E_{g}) falls on a donator/acceptor layer, such as a P3HT/PCBM-BHJ layer, it can be absorbed by the conjugated polymer P3HT. In this case an electron is raised from the n band (HOMO) into the π* band (LUMO) of the polymer; a hole arises there through the now missing electron in the HOMO. Electron and hole are bound by their Coulomb attraction and generally form a Frenkel exciton. After their generation the excitons initially diffuse on the donator-acceptor boundary surface in step 1. There, in step 2, the electron transfer from donator 4, e.g. P3HT, to the acceptor 5, e.g. PBCM, takes place. The resulting electrons and holes drift in step 3, as a result of the electric field, in separate transport paths (holes via P3HT and electrons via PCBM) to the electrodes.

The disclosed layering method of the sintering of organic electroactive materials is not restricted to P3HT/PCBM systems, but can be expanded and transferred for example to materials with the following characteristics:
Generally for production of semiconductor electrodes or semiconductor electrode surfaces, for example also by using silver flakes or gold particles
Production of particle layer systems, such as mixtures and layer sequences of soluble and insoluble inorganic and organic semiconductor materials with any given electron and hole transport characteristics, especially production of homogeneous charge transfer layers
Production of matrix-bound emitter layers
Production of light coupling-out layers on or in optical components and displays.

The at least one organic semiconductor component is provided here as a powder in the inventive method, wherein the powder is not restricted further in accordance with the invention. Preferably the powder is provided as a dry powder, wherein, in accordance with specific forms of implementation, it can also have a little solvent added to it, for example with less that 10% by volume, or less than 5% by volume, related to the mass of the powder. When the powder has a little solvent added to it, it can become sticky, by which its processing, for example during application to the substrate, can be facilitated and also this can mean that less heating of the substrate is required.

The powder may comprise or consist of powder grains with a diameter of 0.01 to 200 μm, preferably 0.5 to 100 μm and especially preferably 1 to 10 μm. With powder grains that are too large compression can be rendered more difficult, while, with powder grains that are too small, suitable domains cannot be formed. The best results are obtained with particle grains with a diameter of 1 to 10 μm, wherein the particle diameter can be determined for example on the basis of a sieve analysis and corresponding sieves with holes of 1 to 10 μm can be used.

When providing the powder it is possible, in accordance with specific forms of implementation, for the organic semiconductor components, for example the at least two compounds, to be put into a solution by means of at least a first solvent, subsequently, by adding a further substance, to be precipitated out and finally for the at least first solvent and the further substance to be removed, for example by sucking them out, filtering them or vaporization of the solvent etc. Suitable substances for dissolving and precipitation are not restricted here and can be suitably selected, depending on the purpose of the application and can also comprise mixtures. Thus for example, when P3HT and PCBM are used, chloroform can be used as a solvent and ethanol as a precipitation reagent. Through this process powders preferably able to be used for sintering can be produced.

After the production of the layer in step b) and/or c), a second intermediate layer and then a second electrical contact (metal such as AL, Cu or ITO, aluminum zinc oxide, doped tin oxide etc.) can be applied and preferably sintered at the same time. As an alternative a second intermediate layer and then a second electrical contact can optionally also be applied by other method steps, such as vapor deposition etc. for example. The second electrical contact can for example also be applied as a fixed layer, by gluing it on. For example the second electrical contact can be realized by introducing a metallic foil. In addition the second electrical contact can also serve as a new under layer/new substrate, to which a new layer can be applied in its turn with the inventive method. Thus, in accordance with the invention, multi-layer structures are also conceivable. A layer can also be applied with an organic (semiconductor) component, so that here too multi-layers or organic coatings can be produced, that can be sintered separately from one another or also together.

In accordance with specific forms of implementation the layer can also be applied to a substrate that does not comprise any electrode material, such as glass for example, and electric contacts can then be applied by way of the powder in step b) or the compressed powder in step c), i.e. likewise on the substrate as well as the layer.

As an alternative the layer can be applied to a temporary substrate (e.g. glass or polymer foil) and subsequently lifted from there in order to be further processed as a self-supporting layer. For example the self-supporting layer can be equipped with a metal foil on the underside and upper side and can be baked on or soldered in.

In order to be able to locate the layer more precisely on the substrate, the application of the powder can be locally restricted in accordance with specific forms of implementation, for example using a frame, also preferably using a frame that is coated, at least on the inner side, with an anti-adhesion coating, especially Teflon®. The shape of the frame here is not especially restricted and can be round/ring-shaped, oval, square, rectangular or another shape. Also the height of the frame is not restricted further, can however preferably be as high as the thickness of the layer that is to be produced by the inventive method, or a greater height. Thus the layer, after production according to specific forms of implementation, can have a thickness of at least 1 μm, preferably at least 10 μm and further preferably at least 100 μm. Towards the top, the thickness of the layer is dependent on the intended usage purpose, but can, in accordance with specific forms of implementation, also amount to several 100 μm (for example x-ray detectors) or more. The material of the frame is not especially restricted and can comprise aluminum, steel, PVC or Teflon®.

Other embodiments provide an organic component, which has been produced by means of the inventive method. The components produced by means of the inventive method are characterized in this case for example by an enhanced charge carrier mobility as a result of an improved layer with organic semiconductors with fewer spaces and thus improved density and a better homogeneous distribution of the materials of the layer. When a dry powder is used solvent residues are also avoided in the organic component. In addition multi-layers can be formed by a simultaneous sintering of a number of layers, in which the individual layers are not influenced by the production process. Thus for example, during coating using solvents, the respective layers already applied and possibly hardened can be dissolved on during application of the next layer by the solvents used, which can lead to a mixing of the layer boundary. Also components can be produced by the inventive method with layers with organic semiconductor components with a thickness of at least 1 μm, preferably at least 10 μm and further preferably at least 100 μm.

In accordance with specific forms of implementation the organic component is an electro-optical component, preferably a photodetector. As well as this component classes such as organic photodiodes, photovoltaic cells, light-emitting diodes or electrochemical cells are also included.

In principle this coating method can be applied for the following component types:
organic light-emitting diode
organic light-emitting electrochemical cell
organic photovoltaics
organic field effect transistor
organic photo detector for different radiation bandwidths.

Through the disclosed method the following features are simultaneously fulfilled: High throughput+homogeneous layers+high material utilization/barely any material losses+no complex process technology+no health implications from solvent surpluses.

The above forms of implementation, embodiments and developments can be combined with one another in any given way, where sensible. Further possible embodiments, developments and implementations of the invention also include combinations not stated explicitly from features of the invention mentioned previously or below in relation to the exemplary embodiments. In particular the person skilled in the art will also add individual aspects as improvements or expansions to the respective basic form of the present invention.

### Examples

Aspects of the invention are presented below on the basis of a few examples of forms of implementation, which do not however restrict this invention.

For example the inventive layering method will be demonstrated below on the basis of the production of an organic photodiode.

As an example of implementation P3HT/PCBM colloids have been developed. The processing of component layers with such materials has previously been realized with wet chemicals and not from the dry phase via sintering.

The problem of producing sinter layers from this type of donator-acceptor materials is a pressing problem for the reasons given above. Therefore the process has been divided into two independent process steps.

### I) Production of P3HT/PCBM Colloid Structures Adapted for Sinter Layers:

First of all, the production of a homogeneously distributed particulate powder from the materials necessary for layer formation is described.

All materials and solvents are cleaned and prepared oxygen-free in a glovebox or under adequate conditions, likewise all work up to the prepared, usable material mixture is carried out under such conditions.

P3HT and PCBM are dissolved in the same mass ratio in chloroform, in a round-bottomed flask. Subsequently the mixture is sonographed and the sonographed mixture is provided with the around 1.5 times volume of ethanol. Adding the ethanol immediately causes the formation of very fine mixed particles homogeneous in their composition, which are slowly deposited after the ultrasound is switched off.

The round-bottomed flask is now connected to a vacuum rotation evaporator with inert gas flushing so that, at the set bath temperature (around 30° C.), the chloroform is largely removed from the mixture.

The ethanolic particle suspension left behind is now sucked out by means of a Schlenk frit and is washed several times with ethanol and dried in the inert gas stream. The yields are almost quantitative.

Before the further processing of the semiconductor material obtained, this is ground up finely in inert gas either in a mortar or in a vibration ball mill. This post processing serves only to form flowable powder after the content of the frit has dried.

### II) Carrying Out the Sintering of Organic Layers:

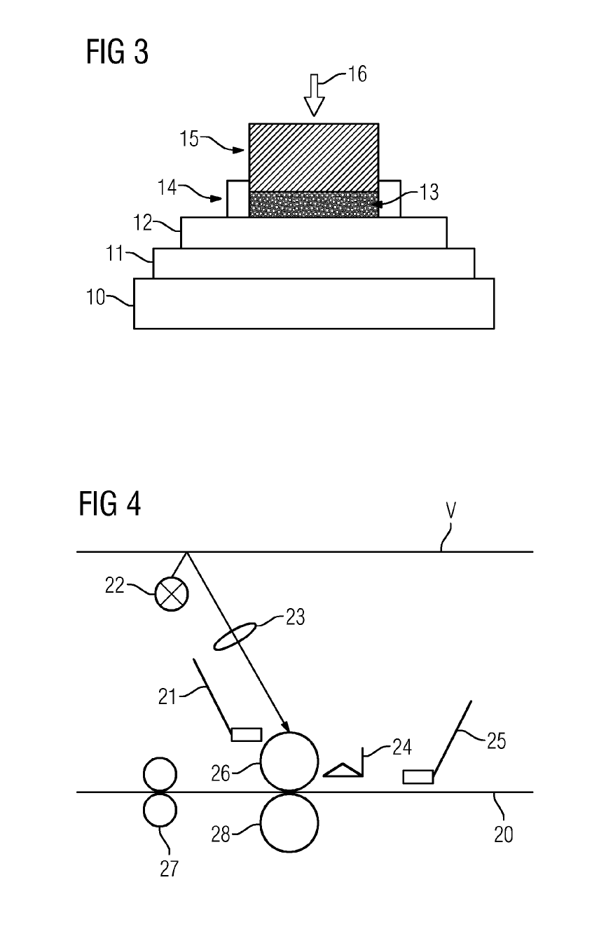

A schematic diagram of a sinter apparatus for organic layers is shown in FIG. 3, which comprises a heating plate 10, a substrate 11, an (optional) lower electrode 12, the layer 13 to be sintered or having been sintered, a filler ring/frame 14, a pressure mold and a weight/pressure exerted from outside 15 for exerting pressure.

In order to realize an organic photodiode with a sintered P3HT/PCBM layer, the active surface of an ITO anode structure (e.g. structured ITO glass) is now covered as the substrate 11 with the finely-crushed colloids of P3HT/PCBM powder. In order to set explicit layer thicknesses and to define the surface to be sintered precisely, a filler ring 13, of which the diameter is greater by around 100 μm than that of the pressure mold (sinter stamp) can be placed on the ITO substrate. Thus the consumption of material is governed very precisely and the sinter edge is homogeneously delimited. At the same time the amount of material before the sinter process is weighed and thereby good control over the later layer thickness is achieved. Here the ITO substrate 11 is located on a heating plate 10 with a temperature regulation from room temperature to >160° C. Via a pressure apparatus the pressure mold 14 (sinter stamp) is pressed in the filler ring 13 onto the colloid P3HT/PCBM powder up to a pressure of around 5 MPa. In addition the heating plate 10 is heated up to a temperature of 140° C. Pressure and temperature now cause a compression of the colloid powder on the ITO anode. After a sinter time of around 5-10 minutes the pressure is released and the pressure mold 14 is finally removed again. A sintered layer 12 fixed to the ITO anode is left behind (layer thickness achieved for this exemplary embodiment; 180 μm, sintering here was without a filler ring however). In order to prevent P3HT/PCBM residues on the pressure mold 14 or a breaking-off of the sintered layer when the pressure mold 14 is pulled off, this mold, made of aluminum or steel for example is coated on its pressure surface with Teflon® (e.g. by means of CVD, Chemical Vapor Deposition). A pressure mold 14 made entirely of Teflon® is also possible. The filler ring 13 can also be coated with Teflon®.

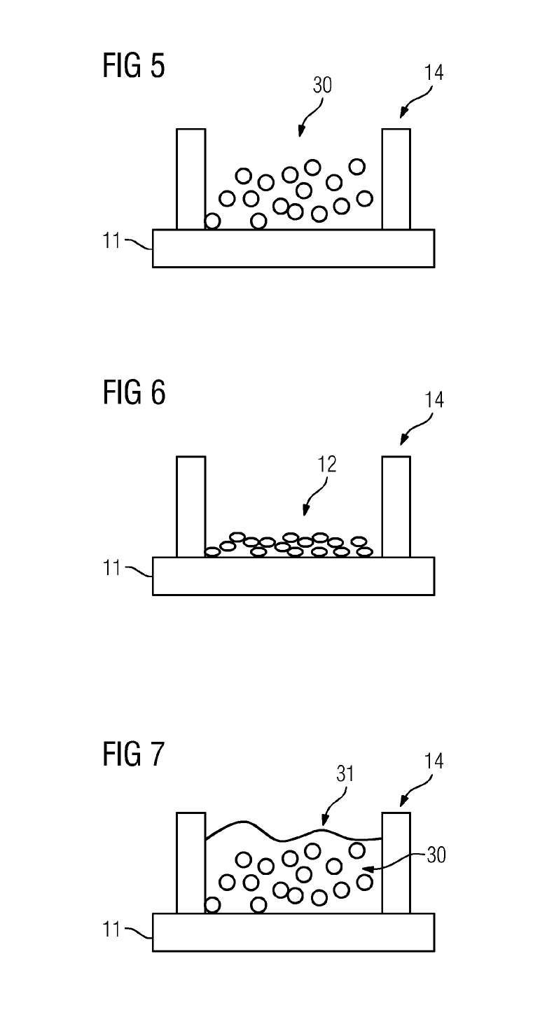

FIGS. 5 and 6 show the sintering mechanism as a microscopic representation. In FIG. 5 the filler ring 14 on the substrate 11 is being filled with uncompressed powder. The distance between the powder particles is large and there is not necessarily a continuous contact. FIG. 6 shows the sintered layer 12 after the compression under pressure and temperature. The particles are touching and their shape has changed by melting and pressing.

After the sintering, an aluminum cathode (layer thickness around 200 nm) is vapor-deposited on the sintered layer by means of physical gas phase deposition. As an alternative it could be shown that it is possible, even during the sinter process, to introduce a piece of punched-out aluminum foil 31 as a top contact (see FIG. 7).

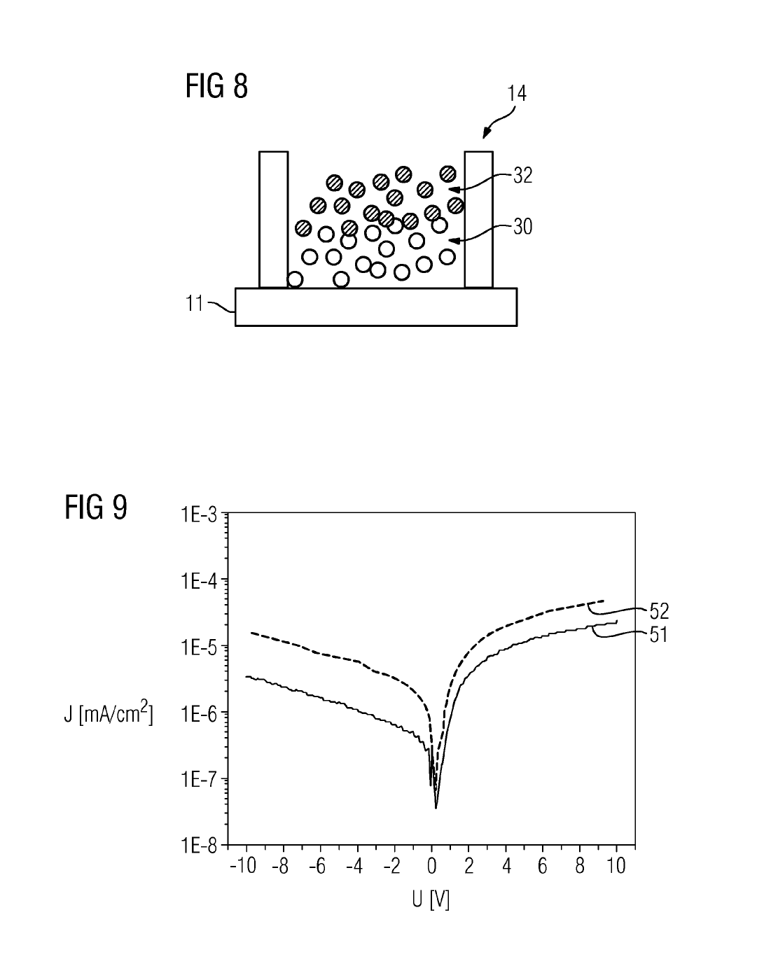

A further alternative for attaching a second contact or a second layer is shown in FIG. 8. In this figure two different powders 30 and 32 are layered one above the other and pressed together.

In FIG. 9 the current density-voltage characteristic of a photodiode with a sintered P3HT/PCBM layer is shown. Both the dark current characteristic 51 and also the light current characteristic 52 are mapped here. Evidently the rectification behavior of a typical organic photodiode is being observed here with a dark current 51 at −10V of 6.9 10⁻⁶ mA/cm² and at +10V of 5.5 10⁻³ mA/cm². Furthermore, on irradiation with light from a halogen lamp, a response of the diode in the form of a light current 52 with 3.7 10⁻³ Ma/cm² at −10V is observed.

Thus the principle feasibility of an organic photodiode with a sintered P3HT/PCBM hetero junction has been able to be demonstrated for the first time.

In FIG. 4 a further form of implementation of a “sinter machine” for a roll-to-roll process is presented. This involves a “heatable rolling train”. In principle there are already machines which perform something like this function, such as in the form of electro-photographic machines (copiers and laser printers), and which can be adapted accordingly for the inventive method. FIG. 4 shows a principle scheme of a copier, which would be capable of producing such sinter layers on flexible substrates 20, were the cartridge 24 to be filled with the described organic semiconductor materials. The imaging drum 26 is electrostatically charged up here by the charging facility 21, light from a light source 22 is reflected by the template V, which maps the desired structure to be imaged, as in copying, and is irradiated via the lens 23 onto the imaging drum 26, and thus accordingly image areas on the imaging drum 26 are formed by erasing the charge with the reflected light. Now the organic semiconductor material is applied by the cartridge 24 on the imaging drum 26 and applied to the substrate 20 charged by the layering device 25, wherein the substrate is guided through the imaging drum 26 and mating roll 28. Heated rolls 27 are provided as a fixing unit, which sinter on the material for example at 140-180° C. All materials of the inventive sinter process are electrostatically active and can be applied from (toner) cartridges. Electrodes can also be applied in this way.

For non-flexible substrates an adequate arrangement of the copier module can be carried out via a linear substrate transport.

The production and efficient fabrication of organic semiconductor layer systems can thus be carried out by R2R processes (for example multiple passes of the substrates in a sinter cascade).

What is claimed is:

1. A method for producing an organic component, the method comprising:
applying a powder comprising at least one organic semiconductor component to a substrate; and
applying pressure to compress the powder to form a layer of organic semiconductor material over the substrate.

2. The method of claim 1, comprising heating the substrate before applying pressure to compress the powder.

3. The method of claim 1, wherein the organic semiconductor component includes at least two compounds.

4. The method of claim 3, comprising:
adding the at least two compounds to a solution using a first solvent,
subsequently precipitating the at least two compounds by adding a further substance, and
removing the first solvent and the further substance.

5. The method of claim 1, wherein the powder comprises powder grains with a diameter of 0.01 μm to 200 μm.

6. The method of claim 1, wherein the substrate has a first electrical contact and a first intermediate layer.

7. The method of claim 1, comprising, after forming the layer, applying a second intermediate layer and a second electrical contact, and sintering the second intermediate layer and second electrical contact along with the layer.

8. The method of claim 7, wherein the second electrical contact comprises a metallic foil.

9. The method of claim 1, comprising applying electrical contacts to the powder before or after compressing the powder.

10. The method of claim 1, wherein the application of the powder is delimited locally using a frame having an anti-adhesion coating.

11. The method of claim 1, wherein the formed layer has a thickness of at least 1 μm.

12. The method of claim 1, wherein pressure is applied using a stamp or a roll having an anti-adhesion coating.

13. An organic component, produced by a process including:
applying a powder comprising at least one organic semiconductor component to a substrate; and
applying pressure to compress the powder to form a layer of organic semiconductor material over the substrate.

14. The organic component as claimed in claim 13, wherein the organic component is an electro-optical component.

15. The organic component as claimed in claim 14, wherein the organic component is a photodetector.

16. The method of claim 1, wherein the powder comprises powder grains with a diameter of 0.5 μm to 100 μm.

17. The method of claim 1, wherein the powder comprises powder grains with a diameter of 1 μm to 10 μm.

18. The method of claim 1, wherein the formed layer has a thickness of at least 10 μm.

19. The method of claim 1, wherein the formed layer has a thickness of at least 100 μm.
